(19) United States
(12) Patent Application Publication
(10) Pub. No.: US 2021/0363632 A1
(43) Pub. Date: Nov. 25, 2021

(54) PROCESS CHAMBER GUIDE, PROCESS CHAMBER, AND METHOD FOR GUIDING A SUBSTRATE CARRIER IN A PROCESS POSITION

(71) Applicant: NexWafe GmbH, Freiburg (DE)

(72) Inventors: Stefan Reber, Gundelfingen (DE); Kai Schillinger, Freiburg (DE); Benjamin Reichhart, Emmendingen-Wasser (DE)

(73) Assignee: NexWafe GmbH, Freiburg (DE)

(21) Appl. No.: 16/497,076

(22) PCT Filed: Mar. 19, 2018
(86) PCT No.: PCT/EP2018/056873

§ 371 Date: Sep. 24, 2019

(30) Foreign Application Priority Data
Mar. 24, 2017 (DE) 10 2017 106 373.0

(51) Int. Cl. C23C 16/44; C23C 16/458; C23C 16/24; C23C 16/54

(52) U.S. Cl. CPC C23C 16/4409; C23C 16/545; C23C 16/24; C23C 16/4583

(57) ABSTRACT

A process chamber guide, designed for linearly guiding a substrate carrier that can be displaced in the process chamber guide in a direction of guidance such that by displacement of the substrate carrier in a process position, an at least regional demarcation of a process chamber guide can be formed by the process chamber guide and substrate carrier. The invention is characterized in that the process chamber guide has a roller bearing for the substrate support and at least one sealing surface, which extends parallel to the direction of guidance and is designed and arranged in such a way that, whenever the substrate carrier arranged in the process chamber guide is in a process position, the sealing surface is spaced apart less than 1 mm from the substrate carrier. The invention further relates to a process chamber and to a method for guiding a substrate carrier in a processing position.

### BACKGROUND

The invention relates to a process chamber guide, a process chamber, and a method for guiding a substrate carrier into a processing position.

For the coating of substrates, for example, for the deposition of semiconductor layers on a seed substrate, substrate carriers are used: the seed substrates are arranged on the substrate carrier. Then, the substrate carrier is moved into a processing position by a process chamber guide.

It is known to provide a lower and an upper process chamber guide for substrate carriers, so that the substrate carriers can be moved in parallel into the process chamber guides and, in the processing position, a process chamber is formed that is bounded on the side by the substrate carriers and on the top and bottom by the process chamber guides. Such a device is known from WO 2013/004851 A1.

### SUMMARY

The present invention is based on the objective of improving the previously known process chamber guide, in order to enable improved processing conditions.

This objective is achieved by a process chamber guide, a process chamber, a device for the chemical deposition of a layer on a substrate, and a method for guiding a substrate carrier into a processing position having one or more features of the invention. Advantageous constructions can be found in the description below and in the claims.

The process chamber guide is preferably designed for performing the method according to the invention, in particular, an advantageous embodiment thereof. The method according to the invention is preferably designed to be performed by the process chamber guide according to the invention, in particular, a preferred embodiment thereof.

The process chamber guide according to the invention is designed for the straight-line guidance of a substrate carrier that can be displaced into the process chamber guide in a guiding direction. In this way, by displacing the substrate carrier into a processing position, a process chamber can be bounded at least in some areas by the process chamber guide and substrate carrier.

An example of this is known from WO 2013/004851 A1 with a process chamber guide formed as a rail 3, into which a substrate carrier 1 can be moved (see FIG. 1 of WO 2013/004851 A1). The substrate carrier 1 and rail 3 bound a process chamber at least in some areas.

For the present invention, it is essential that the process chamber guide has at least one sealing surface that extends parallel to the guiding direction and is designed and arranged such that for substrate carriers arranged in the process chamber guide in the processing position, the sealing surface is spaced less than 1 mm, preferably less than 0.5 mm, in particular, less than 0.2 mm from the substrate carrier.

The invention is based on the knowledge that previous process chamber guides have disadvantages: for example, for pure sliding guides, particles that find their way into the process chamber guide can cause rough movements or can block movements of the parts. Wear debris can also be produced, which can find its way into the process chamber and can reduce the quality of the layer to be deposited. Due to the sealing surface that is spaced less than 1 mm, preferably less than 0.5 mm from the substrate carrier, a sufficient seal between the substrate carrier and process chamber guide is guaranteed, so that only minimal processing gases can escape between the substrate carrier and sealing surface.

The sealing surface is thus used for the at least approximate sealing between the process chamber guide and the substrate carrier in the processing position in the process chamber guide.

To improve the sealing effect, it is advantageous that the sealing surface has, perpendicular to the guiding direction and parallel to the surface of a substrate carrier arranged in the process chamber guide, a width of at least 2 mm, in particular, at least 10 mm, preferably at least 20 mm.

To avoid contact between a substrate carrier guided in the process chamber guide and the sealing surface, the process chamber guide is advantageously designed so that, in the processing position, the sealing surface has a spacing of at least 0.02 mm, in particular, at least 0.05 mm, preferably at least 0.1 mm to the surface of the substrate carrier facing the sealing surface.

The spacing between the sealing surface and the facing surface of the substrate carrier is preferably achieved with guide elements that can be arranged on the process chamber guide and/or on the substrate carrier. The guide elements can be constructed as guide bars, guide rollers, and/or guide channels, in particular, grooves.

The sealing surface extends in the guiding direction advantageously across a sufficient length, in order to enable the construction of a process chamber, in particular, at least across the width of a substrate carrier in the guiding direction. Preferably, the sealing surface extends at least across 0.5 m, in particular, preferably at least across 1 m.

In particular, it is advantageous that the sealing surface extends across the entire length of the process chamber guide in the guiding direction.

Advantageously, the process chamber guide has, in addition to the specified first sealing surface, at least one second sealing surface that extends parallel to the guiding direction and is designed and arranged such that for a substrate carrier arranged in the process chamber guide in the processing position, the substrate carrier is arranged between the two sealing surfaces and the sealing surfaces have a spacing, perpendicular to the guiding direction, which exceeds the thickness of the substrate carrier by less than 1 mm, preferably by less than 0.4 mm, in particular, by less than 0.2 mm. In this way, the sealing effect is increased.

Advantageously, the process chamber guide has a roller bearing for the substrate carrier. In particular, due to temperature differences during the processing, dimensional changes of the substrate carrier and/or the process chamber guide can occur, which can lead to jamming of the substrate carrier in the process chamber guide or to an insufficient seal between the process chamber guide and substrate carrier. The roller bearing avoids these disadvantages by providing good movability of the substrate carrier in the guiding direction even in the event of spatial or time temperature gradients by the roller bearing.

The roller bearing can be arranged alternatively on the substrate carrier. It is also in the scope of the invention that both the process chamber guide and also the substrate carrier have a roller bearing.

Advantageously, guide elements that interact with the roller bearing and prevent lateral displacement perpendicular to the guiding direction are provided. These guide elements can be designed as previously described as guide bars, guide rollers, and/or guide channels, in particular, grooves. Preferably, the guide elements are arranged on the element corresponding to the roller bearing: for a roller bearing arranged on the guide element, the guide elements are preferably arranged on the substrate carrier, in particular, on the side facing the roller bearing in the processing position. For a roller bearing arranged on the substrate carrier, the guide elements are preferably arranged on the process chamber guide, in particular, on the side facing the roller bearing in the processing position.

Advantageously, the process chamber guide has a groove for receiving the substrate carrier. In this way, the sealing surface can be advantageously formed in or on a side wall of the groove. Advantageously, the groove is designed as a rectangular groove. It lies within the scope of the invention that the groove could have rounded edge areas.

In particular, it is thus advantageous that one of the side surfaces of the groove, preferably both side surfaces of the groove are designed as sealing surfaces at least in some areas, advantageously across the entire length of the groove in the guiding direction.

A roller bearing is advantageously arranged on the bottom surface of the groove. Alternatively, the bottom surface of the groove is designed as a rolling surface for a roller bearing of the substrate carrier.

The present invention further relates to a process chamber for vapor deposition of layers with at least one process chamber guide according to the invention, in particular, an advantageous embodiment thereof, and at least one substrate carrier. By the displacement of the substrate carrier in the process chamber guide in a processing position, the process chamber can be bounded at least in some areas. The process chamber has end-wall bounding elements that are connected to the process chamber guide on two opposing sides.

The end-wall bounding elements are preferably arranged such that, in the processing position on two opposing sides, the process chamber is bounded on the ends by the end-wall bounding elements, while on the sides, the process chamber is bounded by the substrate carrier and the process chamber guide.

The substrate carrier preferably has a guide for rollers of the roller bearing of the process chamber guide. In particular, it is advantageous that the substrate carrier has a groove, preferably a rectangular groove for guiding the rollers of the process chamber guide. This ensures a secure guiding of the substrate carrier for movement into the process chamber guide. In particular, a lateral displacement perpendicular to the guiding direction is prevented or at least limited for the rollers by the guiding of the substrate carrier.

In another advantageous construction, the substrate carrier has a roller bearing on the side facing the process chamber guide, so that a low-friction movement of the substrate carrier in the guiding direction of the process chamber guide is achieved.

In one advantageous embodiment, the substrate carrier has a sealing bar that extends in the guiding direction and is arranged such that, in the processing position, the sealing bar is spaced by less than 0.3 mm, preferably less than 0.2 mm, in particular, less than 0.1 mm from the process chamber guide. In this way, an additional sealing and thus increase of the sealing effect between the substrate carrier and process chamber guide is achieved. In addition, this sealing bar prevents a penetration or escape of particles, in particular, into or out of a guiding groove.

Advantageously, the previously mentioned process chamber guide is arranged as a lower process chamber guide of the process chamber and the process chamber also additionally has at least one upper process chamber guide that is connected to the end-wall bounding elements and is arranged such that, in the processing position, the substrate carrier is arranged between the lower and upper process chamber guides. The upper process chamber guide is likewise designed as a process chamber guide according to the invention, in particular, as an advantageous embodiment thereof. Thus, in the processing position, a sealing effect is given on the upper and lower edges of the substrate carrier. On the front and rear edges, the process chamber is bounded by other substrate carriers arranged in front and/or in back in the guiding direction and/or by the end-wall bounding elements.

In one advantageous embodiment, the process chamber is bounded on each of two opposing sides by a substrate carrier:

Advantageously, the process chamber has the previously mentioned substrate carrier as the first substrate carrier and also at least one second substrate carrier. Furthermore, the process chamber has, in addition to lower and upper processing guides as a first process chamber guide pair, at least one additional lower process chamber guide and one additional upper process chamber guide as a second process chamber guide pair. The process chamber guides of the second process chamber guide pair are likewise designed as process chamber guides according to the invention, in particular, as advantageous embodiments thereof.

It is especially advantageous to form multiple process chambers one next to the other. Here, at least three substrate carriers parallel to each other are used, wherein the middle substrate carrier carries two-sided substrates for processing, in particular, for coating. In this way, a first process chamber is formed between the left and middle substrate carriers and a second process chamber is formed between the middle and right substrate carriers. Accordingly, the substrate carriers are guided by three lower and three upper process chamber guides.

Advantageously, the process chamber guide has at least one inlet for a flushing gas. The inlet is arranged such that, in the processing position, flushing gas can be fed in between the process chamber guide and the substrate carrier. This produces the advantage that an undesired deposition in the area between the process chamber guide and the substrate carrier and, in particular, on the roller bearing, can be avoided. Therefore, advantageously, during the process, in particular, during a deposition process, flushing gas is fed in at least during some periods, preferably continuously.

It is within the scope of the invention that flushing gas is fed in with an overpressure relative to the pressure prevailing in the process chamber, so that flushing gas can penetrate—at least minimally—into the process chamber. In this way, a penetration of gases and particles out of the process chamber into the area between the process chamber guide and substrate carrier and especially to the roller bearing is prevented in an especially effective way. Alternatively or additionally, it is advantageous to provide a flushing gas outlet, so that flushing gas can be simultaneously fed and discharged, in order to remove undesired gases or particles from the intermediate space between the process chamber guide and substrate carrier.

In the processing position, the second substrate carrier is arranged between the lower and upper process chamber guides of the second process chamber guide pair and the process chamber is thus formed by the substrate carrier, process chamber guides, and end-wall bounding elements. Here, it is within the scope of the invention that in the guiding direction, the process chamber extends across a length that is greater than the width of the substrate carrier in the guiding direction. In this case, the lateral bounding is realized by the arrangement of multiple substrate carriers one next to the other as described above, in the present construction on two opposing sides.

Advantageously, the lower process chamber guides each have a roller bearing for substrate carriers; in this way, a displacement of the substrate carriers is possible with low resistance.

In particular, it is advantageous that the upper process chamber guides each have a roller bearing, in order to also avoid frictional forces or non-uniform displacement movements due to the associated occurrence of static friction and kinetic friction in the above guides.

Advantageously, each substrate carrier has a sealing bar as described above and the sealing bars are arranged such that, in the processing position, the sealing bars are on facing sides of the substrate carrier. In this way, an especially efficient sealing is achieved.

Advantageously, all substrate carriers of the process chamber have roller bearings on all sides facing the process chamber guides, in order to enable low-friction displacement.

The invention further relates to a device for the chemical deposition of a layer on a substrate, in particular, a seed substrate, with a process chamber according to the invention as described above. Such a device has the advantages specified above.

The present invention is advantageous, in particular, for processes in which semiconductor layers and/or barrier layers are deposited chemically on the seed substrate. The present invention is especially advantageous for processes in which the deposited layer is then removed again from the seed substrate, so that a standalone layer, in particular, a semiconductor layer, is produced using the invention. The deposited layer can be, for example, a silicon layer, a layer containing silicon, such as a silicon nitride layer or silicon carbide layer, or a III-V semiconductor layer, such as a gallium-arsenide layer.

The present invention is advantageously used in the production of semiconductor layers, in particular, silicon layers, for the production of semiconductor components, in particular, large surface-area semiconductor components, such as solar cells. The present invention can also be used to cover existing semiconductor substrates, for example, silicon wafers for solar cell production, for the production of semiconductor components, in particular, large surface-area semiconductor components, such as solar cells. It is often desirable to use such processes to coat the semiconductor substrate with a barrier layer or with another semiconductor layer.

### BRIEF DESCRIPTION OF THE DRAWINGS

Other preferred features and embodiments will be described below with reference to embodiments and the figures. Shown therein are:

FIG. 1 a first embodiment of a process chamber guide with a sealing surface,

FIG. 2 a top view from above on the process chamber guide according to FIG. 1,

FIG. 3 a second embodiment of a process chamber guide with two sealing surfaces,

FIG. 4 a third embodiment of a process chamber guide with four sealing surfaces,

FIG. 5 an embodiment of a process chamber for vapor deposition with a total of four process chamber guides.

### DETAILED DESCRIPTION

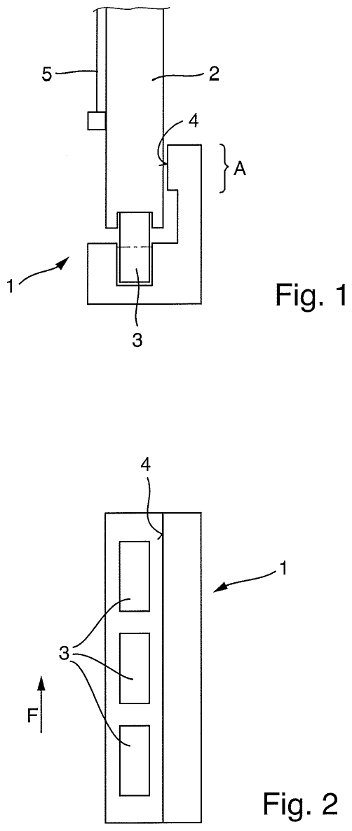

All drawings show schematic illustrations that are not drawn true to scale. The same reference symbols in FIGS. 1 to 5 designate identical or functionally identical elements.

In FIG. 1, a first embodiment of a process chamber guide 1 is shown. The process chamber guide 1 is formed for the straight-line guiding of a substrate carrier 2 that can move into the process chamber guide. The substrate carrier 2 can be moved into the process chamber guide in a guiding direction. In FIG. 1, the guiding direction is perpendicular to the plane of the drawing and points into the drawing. The process chamber guide has a roller bearing that is formed by multiple rollers that are supported so that they can rotate in the process chamber guide. A roller 3 can be seen in FIG. 1. When in use, the substrate carrier is on the roller 3 and can be moved in this way in the guiding direction.

The process chamber guide 1 also has a projection with a sealing surface 4. The sealing surface 4 extends parallel to the guiding direction and is designed and arranged such that, in the processing position according to the illustration in FIG. 1, for the substrate carrier 2 arranged in the process chamber guide, the sealing surface is spaced less than 1 mm, in the present case by 0.2 mm from the substrate carrier. The sealing surface 2 thus extends parallel to a side surface of the substrate carrier 2 on the right in FIG. 1. Between this side surface of the substrate carrier 2 and the sealing surface 4 there is, as described above, a spacing of 0.2 mm. The sealing surface extends perpendicular to the guiding direction across a width A of 20 mm.

The length of the process chamber guide in the guiding direction is dependent on the device in which the process chamber guide is intended to be used, in particular, on the desired length of a process chamber to be formed by the process chamber guide. In the present case, the length of the process chamber guide is 5 m. In the guiding direction, the sealing surface 4 extends across the full length of the process chamber guide and thus also has a length of 5 m. A process chamber is thus bounded laterally by multiple substrate carriers arranged one behind the other in the process chamber guide.

The substrate carrier 2 has multiple holders for seed substrates (in the present case, silicon wafers) on a processing side that is, according to the first embodiment, the side opposite the sealing surface 4 in the processing position and thus the left side according to FIG. 1. A seed substrate 5 is shown as an example.

While in use, in the processing position, a process chamber is formed that represents a three-dimensional enclosed space with other components not shown in FIG. 1. This three-dimensional enclosed space is formed partially by the substrate carrier 2 and by the process chamber guide 1.

A typical process for such a device is the deposition of a semiconductor layer on the seed substrate 5, in particular, a seed substrate formed as a silicon wafer with porosified surface, in particular, an epitaxial deposition. Here, gas exchange between the process chamber (left side of substrate carrier 2) and the outside area (right side of substrate carrier 2) should be avoided.

Due to the sealing surface 4, on one side it is now guaranteed that there is no direct mechanical contact between the sealing surface 4 and substrate carrier 2 and thus displacement of the substrate carrier 2 by the roller bearing is possible with only minimal resistance. Nevertheless, the narrow gap between the sealing surface 4 and the right side of the substrate carrier 2 facing the sealing surface 4 forms a considerable fluid resistance, so that a gas flow through this gap is avoided or at least considerably reduced.

In FIG. 2, a top view from above is shown onto the process chamber guide according to FIG. 1. Here, it can be seen that several rollers 3 are arranged one after the other in the guiding direction F. All rollers of the roller bearing are supported so that they can rotate in the process chamber guide. For reasons of better visibility, only three rollers are shown. Actually, a process chamber guide can have a significantly larger number of rollers, for example, for the length specified here of 5 m, a total of 200 rollers.

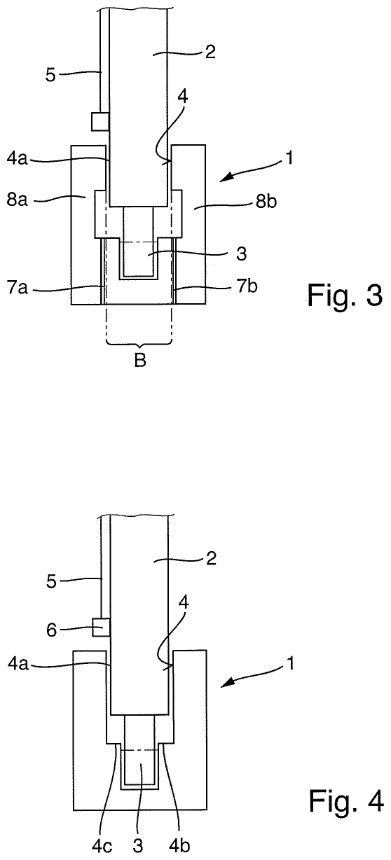

In FIG. 3, a second embodiment of a process chamber guide according to the invention is shown, which is equal in its basic structure to the first embodiment. To avoid repetition, only the essential differences are described below:

The process chamber guide according to FIG. 3 also has, in addition to the specified sealing surface 4 as the first sealing surface, a second sealing surface 4a. The second sealing surface 4a also extends parallel to the guiding direction and is designed and arranged such that, in the processing position, for the substrate carrier 2 arranged in the process chamber guide, the substrate carrier is arranged between the two sealing surfaces 4 and 4a. The sealing surfaces 4 and 4a has a spacing B that exceeds the width of the substrate carrier by less than 0.4 mm, in the present case by approximately 0.2 mm, perpendicular to the guiding direction. For a centrally arranged substrate carrier 2, on each side there is a gap of 0.1 mm to one of the two sealing surfaces 4 and 4a.

The second sealing surface 4a is parallel to the sealing surface 4 and is formed with identical dimensions.

The process chamber guide according to FIG. 3 thus has the advantage that there is a higher fluid resistance for a gas flow starting from the left side of the substrate carrier 2 to the right side of the substrate carrier 2 or vice versa, because on both sides of the substrate carrier, a fluid flow resistance is formed by the sealing surface 4 on one side and the sealing surface 4a on the other side.

In addition, this embodiment has the advantage that the sealing surfaces 4 and 4a are used as a guide for the substrate carrier 2 relative to lateral displacement, that is, horizontal in FIG. 3:

In FIG. 1, the shown substrate carrier 2 has, on the lower end, a groove in which the roller 3 engages. Here, a lateral displacement (horizontal in FIG. 1 and thus perpendicular to the guiding direction) is avoided, because the side walls of the groove of the substrate carrier 2 prevent or at least limit lateral displacement through contact with the side walls of the roller 3.

In the embodiment according to FIG. 3, such a groove of the substrate carrier is not absolutely necessary, because a lateral displacement of the substrate carrier is limited to the right and to the left by the sealing surfaces 4 and 4a. In an alternative, advantageous embodiment, the process chamber guide according to FIG. 3 is nevertheless used with a substrate carrier 2 with a groove according to the illustration in FIG. 1, in order to prevent contact of the substrate carrier with the sealing surfaces 4 and 4a, so that there is no increase in the resistance for displacement of the substrate carrier.

The process chamber guide 1 according to FIG. 3 also has two inlets 7a and 7b for flushing gas, which can be connected to corresponding flushing gas feed lines. In the operating state, flushing gas is fed via the inlets 7a, 7b into the intermediate spaces 8a and 8b between the process chamber guide 1 and substrate carrier 2, so that, in the intermediate spaces 8a and 8b, there is an overpressure relative to the pressure prevailing in the process chamber and in the atmosphere. In this way it is achieved that essentially minimal flushing gas penetrates into the atmosphere or into the process chamber on the sealing surfaces 4 and 4a. In this way, in an especially effective way it is prevented that foreign particles and undesired gases penetrate into the intermediate spaces 8a and 8b and, in particular, negative effects on the function of the roller bearing are prevented. Alternatively or additionally, it is possible to provide inlets for flushing gas on the end side at the start and/or end, preferably both at the start and also at the end of the process chamber guide.

In FIG. 4, a third embodiment of a process chamber guide is shown. Here, the structure is also essentially identical to the structure according to FIG. 3 and, for avoiding repetition, only the essential differences are discussed below:

The process chamber guide according to FIG. 4 has a groove for holding the substrate carrier 2. The groove is designed as a rectangular groove, wherein, the roller bearing with roller 3 is arranged on the bottom surface of the groove. The process chamber guide is designed such that, in interaction with the substrate carrier 2, the spacing between the lateral surfaces 4 and 4a and between the bottom surfaces 4b and 4c of the groove and the respective facing side of the substrate carrier is <0.2 mm, in the present case 0.1 mm. In this way, a fluid resistance is formed by four sealing surfaces 4, 4a, 4b, and 4c, which prevents or at least considerable reduces the gas flow from the left side of the substrate carrier 2 to the right side of the substrate carrier 2 or vice versa.

In addition, the seed substrate 2 according to FIG. 4 has a sealing bar 6. This sealing bar 6 is simultaneously used as the lower holding bar for the seed substrate 5. The sealing bar 6 extends in the guiding direction (into the plane of the drawing) and is arranged such that, in the shown processing position, the sealing bar is spaced by less than 0.5 mm, in the present case by approximately 0.2 mm from the process chamber guide. In this way, an increase of the flow resistance for gas flows into the groove or out of the groove is also achieved.

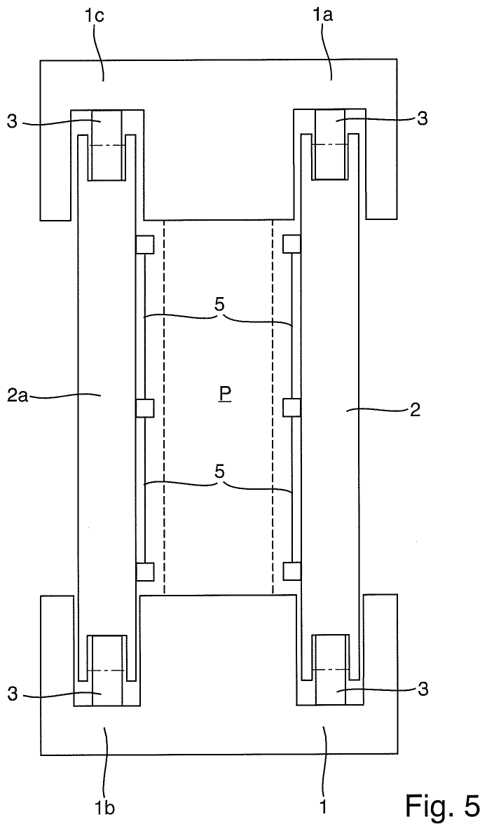

Advantageously, two respective process chamber guides are formed as one piece. This will be explained in more detail using the embodiment of a process chamber according to the invention and the illustration according to FIG. 5:

In FIG. 5, an embodiment of a process chamber according to the invention is shown. The process chamber has a lower process chamber guide 1 and an upper process chamber guide 1a as a first process chamber guide pair. The process chamber also has another lower process chamber guide 1b and another [upper] process chamber guide 1c as a second process chamber guide pair. The lower process chamber guides 1 and 1b are formed as one piece. Likewise, the upper process chamber guides 1a and 1c are formed as one piece. The process chamber also has two substrate carriers 2 and 2a, which each have holders for seed substrates 5.

The process chamber guides 1, 1a, 1b, and 1c are formed according to the process chamber guide shown in FIG. 4 and thus each have a groove for holding the substrate carrier. In the processing position shown in FIG. 5, the substrate carriers are arranged such that the seed substrates are opposite each other. Thus, a process chamber P is formed that is limited on the sides by the substrate carriers 2 and 2a (or by the seed substrates 5 arranged thereon). To the top and bottom, the process chamber is bound by the process chamber guides 1, 1a, 1b, and 1c. On each end, the process chamber has an end-wall bounding element that is connected in a fluid-tight manner to the process chamber guides. The extent of the end-wall bounding element is shown by dashed lines in FIG. 5. The end-wall bounding elements are thus designed such that, on the ends, a gas flow out of the process chamber P is prevented or at least reduced, but a displacement of the substrate carrier 2 and 2a in the guiding direction past the end-wall bounding elements is possible. The end-wall bounding elements are arranged at the start and end of the process chamber guides, with each of them having a length of 5 m. The spacing of the end-wall bounding elements, which are arranged parallel to each other, is thus also approximately 5 mm.

In contrast to the previously described embodiments, for the embodiment according to FIG. 5, the rollers 3 are each arranged on the substrate carriers and run in grooves that are formed in the process chamber guides. In this embodiment, the roller bearings are thus arranged on the substrate carriers.

In this way, a process chamber P is formed that has, in the guiding direction, a length of approximately 5 mm and a width that corresponds approximately to the spacing of the facing surfaces of the substrate carriers 2 and 2a, in the present case, approximately 10 cm. The height of the process chamber corresponds to the distance of the lower process chamber guides to the upper process chamber guides, in the present case approximately 40 cm.

In another embodiment, the process chamber according to FIG. 5 is expanded by another seed substrate carrier, which is arranged on the right next to the seed substrate carrier 2. Accordingly, also for the third seed substrate carrier, the upper and lower process chamber guides are each provided with grooves for rollers. In this way, in addition to the process chamber P shown in FIG. 5, a second process chamber is formed between the seed substrate carrier 2 and the third seed substrate carrier. Accordingly, the seed substrate carrier 2 has, in this embodiment, substrates for processing both on the left side and also on the right side. The third substrate carrier has, accordingly, substrates for processing only on the left side, which is allocated to the second process chamber.

1. A process chamber guide (1, 1a, 1b, 1c), configured for the straight-line guidance of a substrate carrier that is displaceable in the process chamber guide in a guiding direction, so that, by displacement of the substrate carrier into a processing position, a bounding of the process chamber guide (1, 1a, 1b, 1c) comprises at least in some areas the substrate carrier (2, 2a), the process chamber guide comprising:
a sealing surface (4, 4a) extends parallel to the guiding direction and is configured and arranged such that, for the substrate carrier (2, 2a) arranged in the process chamber guide (1, 1a, 1b, 1c), in the processing position, the sealing surface (4, 4a) adapted to be spaced less than 1 mm from the substrate carrier (2, 2a).

2. The process chamber guide (1, 1a, 1b, 1c) according to claim 1, wherein
the sealing surface (4, 4a) has, perpendicular to the guiding direction and parallel to a surface of a substrate carrier arranged in the process chamber guide (1, 1a, 1b, 1c), a width of at least 2 mm.

3. The process chamber guide (1, 1a, 1b, 1c) according to claim 1, further comprising, in addition to the first sealing surface (4, 4a), at least one second sealing surface (4, 4a) that extends parallel to the guiding direction and is configured and arranged such that, for the substrate carrier (2, 2a) arranged in the process chamber guide (1, 1a, 1b, 1c), in the processing position, the first and second sealing surfaces are adapted to be arranged on both sides of the substrate carrier (2, 2a), and
the first and second sealing surfaces have, perpendicular to the guiding direction, a spacing that is adapted to exceed a width of the substrate carrier by less than 0.4 mm.

4. The process chamber guide (1, 1a, 1b, 1c) according to claim 1, further comprising a roller bearing adapted to support the substrate carrier (2, 2a).

5. The process chamber guide (1, 1a, 1b, 1c) according to claim 4, further comprising a groove that is adapted to the substrate carrier.

6. The process chamber guide (1, 1a, 1b, 1c) according to claim 5, wherein
the roller bearing is arranged on a bottom surface of the groove.

7. The process chamber guide (1, 1a, 1b, 1c) according to claim 6, wherein
one of the side surfaces of the groove is formed as a sealing surface (4, 4a) at least in some areas.

8. A process chamber (P) for vapor deposition of silicon layers, comprising:
at least one process chamber guide (1, 1a, 1b, 1c) according to claim 1,
at least one substrate carrier (2, 2a), wherein, by displacement of the substrate carrier in the process chamber guide (1, 1a, 1b, 1c) into a processing position, the process chamber (P) is bounded at least in some areas,
wherein the process chamber guide (1, 1a, 1b, 1c) and the substrate carrier are designed to interact such that, for the substrate carrier (2, 2a) arranged in the process chamber guide (1, 1a, 1b, 1c), the sealing surface (4, 4a) is spaced less than 1 mm from the substrate carrier (2, 2a), and
the process chamber (P) has end-wall bounding elements that are connected to the process chamber guide (1, 1a, 1b, 1c) on two opposing sides.

9. The process chamber (P) according to claim 8, wherein
the substrate carrier (2, 2a) has a guide for rollers of a roller bearing of the process chamber guide, or
the substrate carrier (2, 2a) has a roller bearing that is arranged on a side of the substrate carrier facing the process chamber guide (1, 1a, 1b, 1c).

10. The process chamber (P) according to claim 9, wherein
the substrate carrier (2) further comprises a sealing bar (6) that extends in the guide direction and is arranged such that, in the processing position, the sealing bar (6) is spaced by less than 0.5 mm from the process chamber guide (1, 1a, 1b, 1c).

11. The process chamber (P) according to claim 10, wherein
the process chamber guide (1, 1a, 1b, 1c) forms a lower process chamber guide (1, 1a, 1b, 1c) and the process chamber further comprises at least one upper process chamber guide (1, 1a, 1b, 1c) that is connected to the end-wall bounding elements and is arranged such that, in the processing position, the substrate carrier (2, 2a) is arranged between the lower and the upper process chamber guides (1, 1a, 1b, 1c).

12. The process chamber (P) according to claim 11, wherein the substrate carrier (2, 2a) comprises a first substrate carrier (2, 2a), and at least one second substrate carrier (2, 2a) and, in addition to the lower and upper process chamber guides (1, 1a, 1b, 1c) as a first process chamber guide pair, the process chamber further comprises at least one additional lower process chamber guide (1, 1a, 1b, 1c) and one additional upper process chamber guide (1, 1a, 1b, 1c) as a second process chamber guide pair, which are configured and arranged such that,
in the processing position, the second substrate carrier (2, 2a) is arranged between the lower and upper process chamber guides (1, 1a, 1b, 1c) of the second process chamber guide pair and the process chamber (P) is formed by the substrate carriers (2, 2a), the process chamber guides, and the end-wall bounding elements.

13. The process chamber (P) according to claim 12, wherein
the lower process chamber guides each have a roller bearing for supporting the substrate carriers (2, 2a) or the substrate carriers (2, 2a) each have roller bearings on sides facing the lower process chamber guides.

14. The process chamber (P) according to claim 13, wherein
the upper process chamber guides each have a roller bearing or the substrate carriers (2, 2a) each have roller bearings on sides facing the upper process chamber guides.

15. The process chamber (P) according to claim 14, wherein
each said substrate carrier (2) has a sealing bar (6) that extends in the guide direction and is arranged such that, in the processing position, the sealing bar (6) is spaced by less than 0.5 mm from the respective one of the substrate carriers, and the sealing bars are arranged such that, in the processing position, the sealing bars are on sides of the substrate carrier (2) facing each other.

16. The process chamber (P) according to claim 15, wherein
the process chamber guide (1, 1a, 1b, 1c) has at least one inlet (7a, 7b) for a flushing gas, which is arranged such that, in the processing position, the flushing gas is introducible between the process chamber guide (1, 1a, 1b, 1c) and the substrate carrier (2).

17. A device for the chemical deposition of a silicon layer on a substrate, comprising
a process chamber (P) according to claim 7.

18. A method for guiding a substrate carrier into a processing position, the method comprising:
guiding the substrate carrier (2, 2a) into a process chamber guide (1, 1a, 1b, 1c) using a roller bearing.

19. The method according to claim 18, further comprising:
between the substrate carrier and a process chamber guide, feeding in a flushing gas during a deposition process.
